(19) United States
(12) Patent Application Publication
(10) Pub. No.: US 2023/0222271 A1
(43) Pub. Date: Jul. 13, 2023

(54) AUTOMATIC REAL-TIME DATA GENERATION

(71) Applicant: KONUX GMBH, München (DE)

(72) Inventors: OLGA SPACKOVA, München (DE); ANDRES HERNANDEZ CANSECO, Edingen-Neckarhausen (DE); CHRISTOPHER BOUCHER, HOBART (AU)

(21) Appl. No.: 17/928,448

(22) PCT Filed: May 28, 2021
(86) PCT No.: PCT/EP2021/064399

§ 371 Date: Nov. 29, 2022

(30) Foreign Application Priority Data
May 29, 2020 (EP) 20177575.6

(51) Int. Cl. G06F 30/27; B61L 23/04; B61L 27/53; G06F 30/23

(52) U.S. Cl. CPC G06F 30/27; B61L 23/04; B61L 27/53; G06F 30/23

(57) ABSTRACT

The present invention discloses a system and a method for automatic real-time data generation, particularly in a railway infrastructure. This is facilitated by providing a processing component, a model analyzer, wherein the model analyzer is configured to generate at least one simulation model and a weight analyzer. The weight analyzer is configured to associated statistical weight to at least on infrastructural feature.

### FIELD

The invention relates to automated generation of models to facilitate a real-time monitoring of an infrastructure, such as railway infrastructure.

### BACKGROUND

Wireless Sensor Networks constitute pervasive and distributed computing systems and are potentially one of the most important technologies of this century. They have been specifically identified as a good candidate to become an integral part of the protection of critical infrastructures, such as rail infrastructure. Wired sensor systems have been widely used for a long time in Structural health monitoring (SHM). It is noted that wired systems seem to be commonly used at large scales. However, due to their own limitations, this technique requires high cost and complex installation processes that are inconvenient and have led to the adoption of wireless sensor networks (WSNs) as an alternative approach. Besides providing real time monitoring and alert for preventing damage and failure, this technique can improve the decision-making process in maintenance based on failure prediction rather than on routine operations or execution of work after failure. In addition, the lower power consumption and relatively low costs of theses sensors when compared to traditional sensor technology can reduce the impact of damaged or lost equipment.

Moreover, WSNs have proved that they can be used under severe weather conditions, such as strong wind, storms and snow, whilst the wired traditional technique is vulnerable to damage (e.g., corrosion), vandalism (e.g., cut wire), dirt and nature elements. It is also worth mentioning that WSNs offer many possibilities previously unavailable with traditional sensor technology. In terms of time, the wireless sensing units can be installed with ease and completed in approximately half the time of the wired monitoring system because they require less labour-intensive work and no special care to ensure safe placement of wires on the structure. However, it is preferable to combine periodic visual inspection and a WSN condition monitoring system for maintaining railway structures, as this enables an effective periodic inspection of structures depending on the degree of importance of each monitored component based on the detailed data supplied by the WSN.

The deterioration of rail infrastructure is a significant issue throughout the world. Railway inspection is normally conducted periodically every year or several months. It may take too much time to rapidly detect faults in the track that may cause collapse or huge loss, as is the case in the prompt identification of rail defects. The railway industry needs to improve the process and decision thinking of track maintenance. Hence, condition monitoring of rail infrastructure has become important for setting proper predictive maintenances before defect and failure take place. Structural health monitoring (SHM) has been widely developed over the past decade with many civil engineering applications, such as building, bridge, off-shore structure, in order to enhance the safety and reliability. Condition monitoring can reduce maintenance and its costs by detecting the faults before they can cause damage or prevent rail operations.

In addition, visual inspection requirements can be reduced through automated monitoring. Several sensors may be adopted for railway monitoring such as accelerometers, strain gauges, acoustic emission and inclinometers. Apart from detecting defects in rail infrastructure, other benefits of a monitoring system integrating these sensors are to determine the number of axles, number of trains, their speed, acceleration and weight, which are important for adequate management.

For example, V. J. Hodge, S. O'Keefe, M. Weeks and A. Moulds, “Wireless Sensor Networks for Condition Monitoring in the Railway Industry: A Survey,” in IEEE Transactions on Intelligent Transportation Systems, vol. 16, no. 3, pp. 1088-1106, June 2015 mentions, ‘In recent years, the range of sensing technologies has expanded rapidly, whereas sensor devices have become cheaper. This has led to a rapid expansion in condition monitoring of systems, structures, vehicles, and machinery using sensors. Key factors are the recent advances in networking technologies such as wireless communication and mobile ad hoc networking coupled with the technology to integrate devices. Wireless sensor networks (WSNs) can be used for monitoring the railway infrastructure such as bridges, rail tracks, track beds, and track equipment along with vehicle health monitoring such as chassis, bogies, wheels, and wagons. Condition monitoring reduces human inspection requirements through automated monitoring, reduces maintenance through detecting faults before they escalate, and improves safety and reliability. This is vital for the development, upgrading, and expansion of railway networks. This paper surveys these wireless sensors network technology for monitoring in the railway industry for analysing systems, structures, vehicles, and machinery. This paper focuses on practical engineering solutions, principally, which sensor devices are used and what they are used for; and the identification of sensor configurations and network topologies. It identifies their respective motivations and distinguishes their advantages and disadvantages in a comparative review.’

WO2019185873A1 discloses a method and system for detecting and associating railway related data. The method comprises the steps of capturing at least a first signal from a first sensor applied to railway infrastructure; processing the first signal by at least a first analytical approach to obtain first analytical data. It also comprises capturing at least a second signal from a second sensor and processing the second signal by a second analytical approach to obtain second analytical data. Moreover, the invention provides the further step of associating the first and second analytical data to obtain associated data.

The use of machine learning models to monitor railways or other infrastructures is known to be state of the art. The challenge still lies with the difficulty in collecting realistic data in order to train these models to perform the prediction accurately. For training a machine learning algorithm/model based on sensor data (such as acceleration traces), two options are available: supervised and unsupervised training. In the latter, an unlabelled sample set is presented to the algorithm, which in turn should develop its own features and class definitions. Whereas, in case of supervised learning, which produces more accurate results, it is trained or taught using labelled sample sets.

As need not be stated, the procurement of the labelled sample sets is a manually expensive operation. It also introduces noise and bias to the sample sets. Furthermore, it is still cumbersome to develop a system that allows real-time online analysis of the sensor data by these machine learning models.

### SUMMARY

In light of the above, it is an object of the present invention to overcome or at least alleviate the shortcomings of the prior art. More particularly, it is an object of the present invention to generate synthetic/simulation models to train supervised and un-supervised machine learning algorithms.

In a first embodiment a system is provided. The system comprises at least one processing component, at least one storage component a plurality of sensors nodes, wherein, the processing component is configured to receive sensor data from the sensor nodes. Further the system comprises at least one model analyzer, wherein the model analyzer is configured to generate a simulation model. Furthermore, the system comprises a weight analyzer, wherein the weight analyzer is configured to automatically associate a statistical weight to at least one infrastructural feature. The weight analyzer may comprise a machine learning model analyzer and/or a predictive model analyzer. The predictive model analyzer can be a combination of multiple models.

In some embodiments the at least one sensor node may be configured to be generating the sensor data, such as railway related data. In such embodiments the sensor node may be configured to be installed in a railway infrastructure. In such embodiments the infrastructural feature may comprise at least one railway infrastructural feature.

In some embodiments the infrastructural feature may comprise at least one latent feature. In such embodiments the at least one infrastructural feature is self-learned by the weight analyzer. The weight analyzer may be configured to generate an embedding of the infrastructural feature latent space.

In some embodiments the weight analyzer may further be configured to self-learn the at least one infrastructural feature using the at least one simulation model, wherein the simulation model is generated by the model analyzer. In such embodiments the model analyzer and the weight analyzer may be configured to exchange data. In some further embodiments the model analyzer may be configured to generate the at least one infrastructural feature. In such embodiments the infrastructural feature generated by the model analyzer may be used by the weight analyzer to train the weight analyzer in a semi-supervised and/or un-supervised manner.

In some embodiments the sensor node may comprise at least one of at least one sensor and at least one analog-digital converter and at least one micro controller and at least one of transceiver and at least one power component and at least one memory and at least one processor. Furthermore, the at least one sensor node may comprise a computing unit, wherein for each computing unit the respective at least one of sensor and AC/DC converter and micro controller and transceiver and power component and memory and processor, that the computing unit is configured to access, are integrated into a single device.

In some further embodiments the processor of the sensor node and/or the processing component may comprise a CPU (central processing unit), GPU graphical processing unit), DSP (digital signal processor), APU (accelerator processing unit), ASIC (application-specific integrated circuit), ASIP (application-specific instruction-set processor) or FPGA (field programmable gate array) or any combination thereof.

In some embodiments the storage component and/or the memory of the sensor node may comprise a volatile or non-volatile memory, such as random access memory (RAM), Dynamic RAM (DRAM), Synchronous Dynamic RAM (SDRAM), static RAM (SRAM), Flash Memory, Magneto-resistive RAM (MRAM), Ferroelectric RAM (F-RAM), or Parameter RAM (p-RAM).

In some further embodiments the at least one sensor node may comprise tree-based routing protocol. The sensor node (s) may further be configured to be installed to the railway infrastructure. In such embodiments the railway infrastructure may comprise at least one fixed infrastructure, such as railway tracks, railway switches. In some further embodiments the railway infrastructure may be configured to be cyclically loaded by trains and/or rolling stock with wheel and/or bogie and/or wagon and/or engine.

In some further embodiments the sensor node may comprise a sensor, wherein the sensor node may comprise at least one of: pressure sensor, and accelerometer, and inclinometer, and thermal sensor, and acoustic sensor, and strain gauge sensor, and water pressure sensor, and linear variable displacement transformers, and visual sensor and/or any combination thereof.

In some further embodiments the system may comprise a base station. The base station may comprise a communication gateway between the sensor node(s) and the processing component. It may be noted that the processing component may be configured to be installed on a server. In such embodiments the server may comprise a local and/or a remote server. The sensor node(s) may be configured to transmit sensor data to the base station. In some further embodiments the base station may be configured to pull the sensor data from the at least one sensor node.

In some embodiments the base station may be configured to pull the sensor data from the plurality of sensor nodes lying within a pre-determined distance range of the base station. In such embodiments the pre-determined distance may comprise a radial range from 1 m to 1 Km. The base station may be further configured for bilateral data exchange with a server. The at least one sensor node may further be configured for bilateral data exchange with the server.

In some embodiments the base station may comprise at least one of CAN, Flex Ray, Wi-Fi, Bluetooth, ZigBee, GPRS, EDGE, UMTS, LTE, fiber optics. In some embodiments the server may comprise a long-range communication component, such as GPRS, EDGE, UMTS, LTE or satellite.

In some further embodiments the sensor data may be transmitted to the base station and then sent to the server. In some embodiments the sensor data may be sent directly from the sensor node(s) to the server. In some embodiments the processing component may be configured to collect the sensor data from the at least one of sensor node and base station and server.

In some embodiments the processing component may be configured to generate at least one database using the sensor data. In such embodiments the database may comprise structured database. In some embodiments the processing component may further be configured to generate the database, using the sensor data, based on the sensor associated with the sensor node generating the sensor data. For example, if the sensor data is generated by the acoustic sensor it may be structured into acoustic data.

In some embodiments the processing component may be configured with machine learning algorithms, such as pattern recognition. In such embodiments the processing component may be configured to classify the database into a plurality of classes, such as type of the vehicle, in case of railway infrastructure, speed of the vehicle, etc.

In some embodiments the processing component may further be equipped with signal processing techniques, which may be configured to generate databases based on sensor data. In some embodiments the processing component may be configured to classify the database in to at least one feature, preferably associated with the environment of the sensor node.

In some further embodiments the at least one database and/or the classified database is stored on the storage component. In some embodiments the storage component may be stored on a blockchain ledger. In some further embodiments at least part of the structured database is stored on the blockchain ledger. The storage component may further be configured to store at least one part of sensor data.

In some embodiments the storage component may be configured to store the sensor data for a pre-determined time interval. The storage component may be a cloud-based storage component. In some embodiments the at least one processing component may be configured with the storage component.

In some further embodiments a plurality of processing components may be configured with the at least one storage component. In some further embodiments the at least one sensor node may comprise the storage component. In such embodiments the sensor node may be configured to transmit the sensor data to the storage component.

In some embodiments the model analyzer may be configured to generate at least one simulation model, based on sensor data. In such embodiments the model analyzer may be configured to generate the at least one simulation model based on database, such as structured database. In these embodiments the model analyzer may be configured to automatically parameterize simulation model based on the database. For example, asset characteristics, such as radius of a railway switch and/or type of sleeper and/or physical properties of the material and/or dimensions of the railway components and/or stiffness characteristics and/or boundary conditions and/or maintenance data and/or any combination thereof. In such embodiments the simulation model parameters can be calibrated with an updated sensor data.

In some further embodiments the model analyzer may be configured to generate the at least one simulation model based on time-series analysis. The simulation model may comprise a physical model, such as a FEM model, MBS (Multi-Body simulation model), structural dynamics model, and the alike. The simulation models can be generated using conventional analytical methods or numerical methods such as Finite Element Method, Multi-Body-Simulation method, Boundary element method, Finite Difference Method, Finite volume method, lumped-parameter method or their combinations.

In some embodiments the model analyzer may be configured to generate at least a portion of the simulation model based on a user input, wherein the user input may be inputted via user interface, such as a computing device, to the processing component. The user input may comprise parameters for the simulation model(s). In some further embodiments the model analyzer may be configured to generate at least one simulation model based on machine learning methods. Furthermore, the model analyzer may be configured to generate at least one simulation model based on an expert knowledgebase, such as known properties of material, etc.

In some further embodiments the model analyzer may be configured to generate at least a portion of the simulation model based on a regression analysis and/or physics-based model and/or break-point detection method and/or physical-structural-dynamics model and/or physical environment of the sensor node and/or physical deterioration model and/or statistical deterioration model and/or Monte Carlo risk analysis method and/or behavior of a physical system and/or finite element model.

In some further embodiments the model analyzer may be configured to fuse at least one noise model to the simulation model. In such embodiments the model analyzer may be configured to generate the noise model, preferably based on the database. In some embodiments the model analyzer may comprise a noise encoder. The noise encoder may be configured with machine learning algorithms, such as generative adversarial network (GAN). The noise encoder may further be configured with additive synthesis. In such embodiments the noise encoder may be configured to generate the noise model. Further, the model analyzer may be configured to generate at least one noise fused simulation model. In such embodiments the noise fused simulation model may comprise synthetic data which can be used to train the weight analyzer.

In some embodiments the model analyzer may be configured to store the synthetic data on the storage component. In some embodiments the processing component may comprise a noise decoder. The noise decoder may be configured to determine a noise pattern in the database. It may be noted that noise is the undesirable data, for example weather conditions in case of railway data. In some embodiments the noise decoder may be configured to automatically learn the at least one noise pattern from past sensor data, preferably using semi-supervised and/or unsupervised machine learning techniques.

In some embodiments the noise decode may be configured to automatically learn the at least one noise pattern from historic structured database. The noise decoder may further be configured to automatically learn the at least one noise pattern using the noise fused simulation model/synthetic data. In some embodiments the processing component may be configured to automatically calibrate the learned noise from the database and/or the structured database.

In some further embodiments the processing component can further be configured to automatically calibrate the learned noise from the sensor/input data. In a further embodiment the processing component may be configured to learn at least one class/label from the database, one of the class may comprise the noise pattern.

In some embodiments the weight analyzer may comprise the noise decoder. In some embodiments the weight analyzer may comprise machine learning techniques, such as deep learning. The weight analyzer may further be configured with convolutional neural networks (CNNs). The weight analyzer may further be configured to associate the statistical weight to the at least one infrastructural feature of a latent feature embedding. In such embodiments the weight analyzer may be configured to automatically generate the latent feature space/embedding.

In some further embodiments the latent feature space/embedding may automatically be generated based on the at least one simulation model. In a further embodiment the latent feature space/embedding may automatically be generated based on the noise fused simulation model/synthetic data. In some embodiments the latent feature space/embedding may be generated based on the sensor data and/or the database and/or the structured database. In some embodiments the latent feature space/embedding may be configured to be generated by the processing component.

In some embodiments the weight analyzer is configured to enable a bilateral transmission with the processing component. In some embodiments the weight analyzer may also be configured to access the storage component.

In some embodiments each processing component may comprise a computing unit, wherein for each computing unit the respective storage component, that the computing unit is configured to access, are integrated into a single device. In such embodiments the system may comprise edge computing technique.

In some embodiments each processing component may comprise the computing unit, wherein for each computing unit the respective model analyzer, that the computing unit is configured to access, are integrated into a single device.

In some embodiments each processing component may comprise the computing unit, wherein for each computing unit the respective storage component and the weight analyzer and the server, that the computing unit is configured to access, are integrated into a single device.

In some embodiments each processing component may comprises the computing unit, wherein for each computing unit the respective noise encoder, that the computing unit is configured to access, are integrated into a single device.

In a further embodiment the processing component may be configured to extract sensor data, wherein the sensor data comprises load data. In such embodiment the model analyzer may be configured to self-learn the at least one infrastructural feature from past load data. In some embodiments the processing component may further be configured to automatically determine a load factor, based on load data. In such embodiments the load factor may comprise a numeric value and/or alphanumeric value, preferably based on weight and/or speed and/or quantity of rolling stock in the railway structure. In such embodiments the model analyzer may further be configured to generate the physical degradation model based on load data.

In a second embodiment a method which can be performed on the system is disclosed.

In a third embodiment a device configured to provide an interactive model analysis is disclosed.

In a fourth embodiment a use of the system to carry out the method is disclosed.

In a fifth embodiment a computer program product is disclosed.

The invention is further described with the following numbered embodiments.

Below, system embodiments will be discussed. These embodiments are abbreviated by the letter “S” followed by a number. Whenever reference is herein made to “system embodiments”, these embodiments are meant.
S1. A system, comprising:
   a. at least one processing component;
   b. at least one storage component;
   c. a plurality of sensors nodes;
   d. wherein, the processing component is configured to receive sensor data from the sensor nodes,
   e. at least one model analyzer, configured to generate a simulation model; and
   f. a weight analyzer, configured to automatically associate a statistical weight to at least one infrastructural feature.
S2. The system according to the preceding embodiment wherein the at least one sensor node is configured to be generating the sensor data, such as railway related data.
S3. The system according to any of the preceding embodiments wherein the infrastructural feature comprises at least one railway infrastructural feature.
S4. The system according to any of the preceding embodiments wherein the infrastructural feature further comprises at least one latent feature.
S5. The system according to any of the preceding embodiments wherein the at least one infrastructural feature is self-learned by the weight analyzer.
S6. The system according to any of the preceding embodiments wherein the at least one infrastructural feature is self-learned by the weight analyzer, preferably using the at least one simulation model.
S7. The system according to any of the preceding embodiments wherein the model analyzer is configured to generate the at least one infrastructural feature.
S8. The system according to any of the preceding embodiments wherein the sensor node comprises at least one of at least one sensor and at least one analog-digital converter and at least one micro controller and at least one of transceiver and at least one power component and at least one memory and at least one processor.
S9. The system according to any of the preceding embodiments and wherein each sensor node comprises the computing unit, wherein for each computing unit the respective at least one of sensor and AC/DC converter and micro controller and transceiver and power component and memory and processor, that the computing unit is configured to access, are integrated into a single device.
S10. The system according to the preceding two embodiments wherein the processor comprises a CPU (central processing unit), GPU graphical processing unit), DSP (digital signal processor), APU (accelerator processing unit), ASIC (application-specific integrated circuit), ASIP (application-specific instruction-set processor) or FPGA (field programmable gate array) or any combination thereof.
S11. The system according to any of the preceding embodiments and features of S7 wherein the memory comprises a volatile or non-volatile memory, such as random access memory (RAM), Dynamic RAM (DRAM), Synchronous Dynamic RAM (SDRAM), static RAM (SRAM), Flash Memory, Magneto-resistive RAM (MRAM), Ferroelectric RAM (F-RAM), or Parameter RAM (p-RAM).
S12. The system according to any of the preceding embodiments wherein the sensor node(s) comprises tree-based routing protocol.
S13. The system according to any of the preceding embodiments wherein the sensor node (s) is configured to be installed to the railway infrastructure.
S14. The system according to the preceding embodiment wherein the railway infrastructure comprises at least one fixed infrastructure, such as railway tracks, railway switches.
S15. The system according to the preceding two embodiments wherein the railway infrastructure is configured to be cyclically loaded by trains and/or rolling stock with wheel and/or bogie and/or wagon and/or engine.
S16. The system according to any of the preceding embodiments wherein the sensor node may comprise at least one of:
   pressure sensor; and
   accelerometer; and
   inclinometer; and
   thermal sensor; and
   acoustic sensor; and
   strain gauge sensor; and
   water pressure sensor; and
   liner variable displacement transformers; and
   visual sensor.
S17. The system according to any of the preceding embodiments wherein the system comprises a base station.
S18. The system according to any of the preceding embodiments wherein the sensor node is configured to transmit sensor data to the base station.
S19. The system according to any of the preceding embodiments wherein the base station is configured to pull the sensor data from the at least one sensor node.
S20. The system according to any of the preceding embodiments wherein the base station is configured to pull the sensor data from the plurality of sensor nodes lying within a pre-determined distance range of the base station.
S21. The system according to the preceding embodiment wherein the pre-determined comprises a distance range from 1 m to 1 Km.
S22. The system according to any of the preceding embodiments wherein the base station is further configured for bilateral data exchange with a server.
S23. The system according to any of the preceding embodiments wherein the at least one sensor node is configured for bilateral data exchange with the server.
S24. The system according to any of the preceding embodiments wherein the base station comprises at least one of CAN, Flex Ray, Wi-Fi, Bluetooth, ZigBee, GPRS, EDGE, UMTS, LTE, fiber optics.
S25. The system according to any of the preceding embodiments wherein the server is a remote server.
S26. The system according to any of the preceding embodiments wherein the server with a long-range communication component, such as GPRS, EDGE, UMTS, LTE or satellite.
S27. The system according to any of the preceding embodiments wherein the sensor data is transmitted to the base station and then sent to the server.
S28. The system according to any of the preceding embodiments wherein the sensor data is sent directly from the sensor node(s) to the server.

### Embodiments Related to the Processing Component

S29. The system according to any of the preceding embodiments wherein the processing component is configured to collect the sensor data from the at least one of sensor node and base station and server.
S30. The system according to any of the preceding embodiments wherein the processing component is configured to generate at least one database using the sensor data.
S31. The system according to any of the preceding embodiments wherein the database comprises a structured database.
S32. The system according to the preceding embodiment wherein the processing component is configured to generate the database, using the sensor data, based on the sensor associated with the sensor node generating the sensor data.
S33. The system according to any of the preceding embodiments wherein the processing component is configured with machine learning algorithms, preferably pattern recognition.
S34. The system according to any of the preceding embodiments wherein the processing component further comprises signal processing.
S35. The system according to the preceding embodiment wherein the processing component is further configured to automatically classify at least a portion of the database.
S36. The system according to the preceding embodiment wherein processing component is configured to classify the database in to at least one feature, preferably associated with the environment of the sensor node.

### Embodiments Related to the Storage Component

S37. The system according to any of the preceding embodiments wherein the at least one of database and the assigned class is stored on the storage component.
S38. The system according to any of the preceding embodiment wherein the storage component comprises a volatile or non-volatile memory, such as random access memory (RAM), Dynamic RAM (DRAM), Synchronous Dynamic RAM (SDRAM), static RAM (SRAM), Flash Memory, Magneto-resistive RAM (MRAM), Ferroelectric RAM (F-RAM), or Parameter RAM (p-RAM).
S39. The system according to any of the preceding embodiments wherein the storage component is configured to comprise a blockchain ledger.
S40. The system according to any of the preceding embodiments wherein the at least part of the structured database is stored on the blockchain ledger.
S41. The system according to any of the preceding embodiments wherein the storage component is further configured to store at least a part of sensor data.
S42. The system according to any of the preceding embodiments wherein the storage component is configured to store the sensor data for a pre-determined time interval.
S43. The system according to any of the preceding embodiments wherein the storage component is a cloud-based storage component.
S44. The system according to any of the preceding embodiments wherein each processing component is configured with the storage component.
S45. The system according to any of the preceding embodiments wherein a plurality of processing components is configured with the at least one storage component.
S46. The system according to any of the preceding embodiments wherein each sensor node is configured with the storage component.
S47. The system according to any of the preceding embodiments wherein the sensor node is configured to transmit the sensor data to the storage component.

### Embodiments Related to the Model Analyzer

S48. The system according to any of the preceding embodiments wherein the model analyzer is configured to generate at least one simulation model, preferably based on sensor data.
S49. The system according to any of the preceding embodiments wherein the model analyzer is configured to generate at least one simulation model based on structured database.
S50. The system according to the preceding embodiment wherein the model analyzer is configured to generate at least one simulation model based on a time-series analysis.
S51. The system according to any of the preceding embodiments wherein the model analyzer is configured to generate at least a portion of the simulation model based on a user input.
S52. The system according to any of the preceding embodiments wherein the model analyzer is configured to generate at least one simulation model based on machine learning methods.
S53. The system according to any of the preceding embodiments wherein the model analyzer is configured to generate at least one simulation model based on an expert knowledgebase.
S54. The system according to any of the preceding embodiments wherein the model analyzer is configured to generate at least one simulation model based on a regression analysis.
S55. The system according to any of the preceding embodiments wherein the model analyzer is configured to generate at least one simulation model based on a physics-based model.
S56. The system according to any of the preceding embodiments wherein the model analyzer is configured to generate at least one simulation model based on a break-point detection method.
S57. The system according to any of the preceding embodiments wherein the model analyzer is configured to generate at least one simulation model based on a physical-structural-dynamics model.
S58. The system according to any of the preceding embodiments wherein the model analyzer is configured to generate at least one simulation model based on physical environment of the sensor node.
S59. The system according to any of the preceding embodiments wherein the model analyzer is configured to generate at least one simulation model based on a physical deterioration model.
S60. The system according to any of the preceding embodiments wherein the model analyzer is configured to generate at least one simulation model based on a statistical deterioration model.
S61. The system according to any of the preceding embodiments wherein the model analyzer is configured to generate at least one simulation model based on Monte Carlo risk analysis method.
S62. The system according to any of the preceding embodiments wherein the model analyzer is configured to generate at least one simulation model based on a behavior of a physical system.
S63. The system according to any of the preceding embodiments wherein the model analyzer is configured to generate at least one simulation model based on finite element model.
S64. The system according to any of the preceding embodiments wherein the model analyzer is configured to fuse at least one noise model to the simulation model.
S65. The system according to any of the preceding embodiments wherein the model analyzer is configured to generate the noise model.
S66. The system according to any of the preceding embodiments wherein the model analyzer is configured to generate the noise model based on the database.
S67. The system according to any of the preceding embodiments wherein the model analyzer comprises a noise encoder.
S68. The system according to the preceding two embodiments wherein the noise encoder is configured with machine learning algorithms, preferably generative adversarial network (GAN).
S69. The system according to any of the preceding embodiments wherein the noise encoder further configured for additive synthesis.
S70. The system according to any of the preceding embodiments wherein the model analyzer is configured to generate at least one noise fused simulation model and/or synthetic data.
S71. The system according to any of the preceding embodiments wherein the model analyzer is further configured to store the noise fused simulation model on the storage component.
S72. The system according to any of the preceding embodiments wherein the model analyzer is configured to store the simulation model on the storage component.
S73. The system according to any of the preceding embodiments wherein the processing component is configured to access the storage component.

### Embodiments Related to Noise Decoupling

S74. The system according to any of the preceding embodiments wherein the processing component comprises a noise decoder.
S75. The system according to any of the preceding embodiments wherein the processing component is configured to automatically determine a noise pattern in the database.
S76. The system according to any of the preceding embodiments wherein the noise decoder is configured to automatically learn the at least one noise pattern from past sensor data.
S77. The system according to any of the preceding embodiments wherein the noise decoder is configured to automatically learn the at least one noise pattern from past structured database.
S78. The system according to any of the preceding embodiments wherein the noise decoder is further configured to automatically learn the at least one noise pattern using the noise fused simulation model.
S79. The system according to any of the preceding embodiments wherein the processing component is further configured to automatically calibrate the learned noise from the structured database.
S80. The system according to any of the preceding embodiments wherein the processing component is further configured to automatically calibrate the learned noise from the input data.
S81. The system according to any of the preceding embodiments and features of S27 wherein the label comprises the noise pattern.
S82. The system according to any of the preceding embodiments wherein the weight analyzer comprises the noise decoder.

### Embodiments Related to the Weight Analyzer

S83. The system according to any of the preceding embodiments wherein the weight analyzer comprises deep learning techniques.
S84. The system according to the preceding embodiment wherein the weight analyzer further comprises convolutional neural networks (CNNs).
S85. The system according to any of the preceding embodiments wherein the weight analyzer is configured to associate the statistical weight to the at least one infrastructural feature of the latent feature space.
S86. The system according to any of the preceding embodiments wherein the latent feature space is configured to be automatically generated by the weight analyzer.
S87. The system according to any of the preceding embodiments wherein the latent feature space is configured to be automatically generated based on the simulation model.
S88. The system according to any of the preceding embodiments wherein the latent feature space is automatically generated based on the noise fused simulation model.
S89. The system according to any of the preceding embodiments wherein the latent feature space is automatically generated based on the sensor data.
S90. The system according to any of the preceding embodiments wherein the latent feature space is automatically generated based on the structured database.
S91. The system according to any of the preceding embodiments wherein the latent feature space is automatically generated by the processing component.
S92. The system according to any of the preceding embodiments wherein the weight analyzer is configured for a bilateral transmission with the processing component.
S93. The system according to any of the preceding embodiments wherein the weight analyzer is further configured to access the storage component.
S94. The system according to any of the preceding embodiments wherein the system is configured to generate the latent feature space.
S95. The system according to any of the preceding embodiments wherein the processing component comprises the weight analyzer.

### Embodiments Related to Computing Unit

S96. System according to any of the preceding embodiments wherein each processing component comprises a computing unit, wherein for each computing unit the respective storage component, that the computing unit is configured to access, are integrated into a single device.
S97. System according to any of the preceding embodiments wherein each processing component comprises the computing unit, wherein for each computing unit the respective model analyzer, that the computing unit is configured to access, are integrated into a single device.
S98. System according to any of the preceding embodiments and wherein each processing component comprises the computing unit, wherein for each computing unit the respective storage component and the weight analyzer and the server, that the computing unit is configured to access, are integrated into a single device.
S99. System according to any of the preceding embodiments and wherein each processing component comprises the computing unit, wherein for each computing unit the respective noise encoder, that the computing unit is configured to access, are integrated into a single device.
S100. System according to any of the preceding embodiments wherein the processing component is configured to extract sensor data from the at least one sensor node, wherein the sensor data comprises load data.
S101. System according to the preceding embodiment wherein the model analyzer is further configured to automatically self-learn the at least one feature from past load data.
S102. System according to any of the preceding embodiments wherein the processing component is further configured to automatically determine a load factor, preferably based on load data.
S103. System according to the preceding embodiment wherein the load factor comprises a numeric value and/or alphanumeric value, preferably based on weight and/or speed and/or quantity of rolling stock in the railway structure.
5104. System according to any of the preceding embodiments wherein the model analyzer is further configured to generate the physical degradation model based on the load data.

Below, method embodiments will be discussed. These embodiments are abbreviated by the letter “M” followed by a number. Whenever reference is herein made to “method embodiments”, these embodiments are meant.
M1. A method comprising the step of:
   a. obtaining sensor data from at least one or a plurality of sensor node(s);
   b. generating simulation model(s);
   c. automatically fusing at least a portion of the sensor data with the simulation model; and
   d. automatically predicting at least one infrastructural feature, preferably associated with the sensor node.
M2. The method according to the preceding embodiment wherein the method comprises carrying out on the system according to any of the preceding system embodiments.
M3. The method according to any of the preceding embodiments wherein the method comprises storing the sensor data on a storing component.
M4. The method according to any of the preceding embodiments wherein the method further comprises the step of generating at least one noise model.
M5. The method according to any of the preceding embodiments wherein the method comprises fusing the noise model with the simulation-based model.
M6. The method according to any of the preceding embodiments wherein the method comprises generating the noise model based on the sensor data.

Below, device embodiments will be discussed. These embodiments are abbreviated by the letter “D” followed by a number. Whenever reference is herein made to “device embodiments”, these embodiments are meant.
D1. A device comprising:
   a. a device processing component, configured for an interactive model analysis;
   b. an interface, configured to pull at least one user input;
   c. a memory component, configured to store the user input.
D2. The device according to the preceding embodiment wherein the device processing component is configured to automatically diagnose and refine the at least one model.
D3. The device according to any of the preceding embodiments wherein the device is further configured with machine learning techniques, preferably machine learning classifiers.
D4. The device according to any of the preceding embodiments wherein the device processing component is configured to perform interactive model analysis based on the user input.
D5. The device according to any of the preceding embodiments wherein the memory component comprises a volatile or non-volatile memory, such as random access memory (RAM), Dynamic RAM (DRAM), Synchronous Dynamic RAM (SDRAM), static RAM (SRAM), Flash Memory, Magneto-resistive RAM (MRAM), Ferroelectric RAM (F-RAM), or Parameter RAM (p-RAM).
D6. The device according to any of the preceding embodiments wherein the device processing component comprises at least one at least one processor, such as, a CPU (central processing unit), GPU graphical processing unit), DSP (digital signal processor), APU (accelerator processing unit), ASIC (application-specific integrated circuit), ASIP (application-specific instruction-set processor) or FPGA (field programmable gate array) or any combination thereof.
D7. The device according to any of the preceding device embodiments, wherein the device is configured to carry out the steps of the method according to any of the preceding method embodiments.

Below, use embodiments will be discussed. These embodiments are abbreviated by the letter “U” followed by a number. Whenever reference is herein made to “use embodiments”, these embodiments are meant.
U1. Use of the system according to any of the preceding system embodiments for carrying out the method according to any of the preceding method embodiments.
U2. Use of the method according to any of the preceding method embodiments, the device according to any of the preceding device embodiments and the system according to any of the preceding system embodiments for generating and analysing synthetic data.

Below, program embodiments will be discussed. These embodiments are abbreviated by the letter “P” followed by a number. Whenever reference is herein made to “program embodiments”, these embodiments are meant.
P1. A computer program product comprising instructions, which, when the program is executed by a user device, causes a user device to perform the method steps according to any method embodiment, which have to be executed on the user device, wherein the user device is according to any system embodiment that comprises a user device that is compatible to said method embodiment.
P2. A computer program product comprising instructions, which, when the program is executed by a combination of a server and user device, cause the server and the user device to perform the method steps according to any method embodiment, which have to be executed on the server and the user device, wherein the user device and the server is according to any system embodiment that comprises a sever and/or the user device that is compatible to said method embodiment.
P3. A computer program product comprising instructions, which, when the program is executed by a server, cause the server to perform the method steps according to any method embodiment, which have to be executed on the server, wherein the server is according to any system embodiment that comprises a server that is compatible to said method embodiment.
P4. A computer program product comprising instructions, which, when the program is executed by a processing component, cause the processing component to perform the method steps according to any method embodiment, which have to be executed on the processing component, wherein the processing component is according to any system embodiment that comprises a processing component that is compatible to said method embodiment.

### BRIEF DESCRIPTION OF THE DRAWINGS

The present invention will now be described with reference to the accompanying drawings, which illustrate embodiments of the invention. These embodiments should only exemplify, but not limit, the present invention.

FIG. 1 schematically depicts an embodiment of a sensor node routing in a railway infrastructure.

FIG. 2 depicts a system embodiment according to an aspect of the present invention.

FIG. 3 schematically illustrates a data flow diagram related to the system.

FIG. 4 schematically shows an exemplary operation of the system.

FIG. 5 depicts the steps of a method according to an aspect of the present invention.

FIG. 6 depicts an exemplary representation of sensor data, particularly load data.

### DETAILED DESCRIPTION OF THE DRAWINGS

In the following description, a series of features and/or steps are described. The skilled person will appreciate that unless explicitly required and/or unless requires by the context, the order of features and steps is not critical for the resulting configuration and its effect. Further, it will be apparent to the skilled person that irrespective of the order of features and steps, the presence or absence of time delay between steps can be present between some or all of the described steps.

It is noted that not all the drawings carry all the reference signs. Instead, in some of the drawings, some of the reference signs have been omitted for sake of brevity and simplicity of illustration. Embodiments of the present invention will now be described with reference to the accompanying drawings.

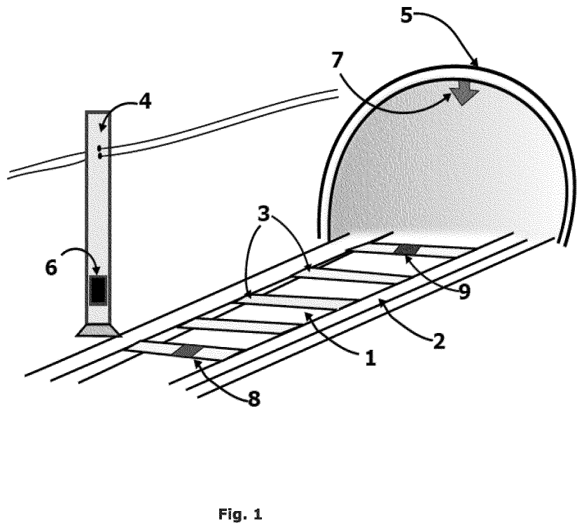

FIG. 1 illustrates an embodiment of a sensor node 1-9 routing in a railway infrastructure. There is shown an example of a railway section with the railway itself, comprising rails and sleepers. Instead of the sleepers also a solid bed for the rails can be provided. Moreover, a mast that is just one further example of constructional elements that are usually arranged at or in the vicinity of railways. A sensor node 1-9 can be arranged on one or more of the sleepers. The sensor 10 can comprise an acceleration sensor and/or any other kind of railway specific sensor. The sensor node 1-9 can further comprise a wireless sensor network. The sensor node can transmit data to a base station (not shown here). The base station can be installed to the railway infrastructure. The base station can also be installed in the surroundings of the railway infrastructure. The base station can also be a remote base station. The communication module between the base station and the sensor node (s) can comprise, for example Xbee with a frequency of 868 MHz.

The sensor node(s) 1-9 can also be installed in cases and inserted inside the railway infrastructure, for example inside a special hole carved into the concrete. The case can also be attached to the railway infrastructure using fixers. The sensor node 1-9 can be obtaining sensor data based on acceleration, inclination, distance, etc.

The sensor node 1-9 may further be divided into group, for example based on the distance. The sensor node 1-9 lying within a pre-determined distance may be controlled by one base station. The sensor node 1-9 can also be installed on the moving railway infrastructure such as on-board of a vehicle. The sensor node 1-9 can comprise an amplifier to amplify any signal received by the base station.

The sensor nodes 1-9 can be installed such that the sensor node lying within one group can communicate with their base station in one-hop. The base station can receive information from its ‘neighbors’ and retransmit all the information to the server 800.

The sensor node 1-9 can comprise sensor(s). The sensor can be accelerometers, such as Sensor4PRI for example ADCL 345, SQ-SVS etc. The sensor node 1-9 can comprise inclinometers, such as SQ-SI-360DA, SCA100T-D2, ADXL345 etc.

The sensor node can further comprise distance sensors. The distance sensors can be configured to at least measure the distance between slab tracks, using infrared and/or ultrasonic. The distance sensor can be for example, MB1043, SRF08, PING, etc.

The sensor node 1-9 can comprise visual sensors, such as 3D cameras, speed enforcement cameras, traffic enforcement cameras, etc. It may be noted that sensor node 1-9 may comprise sensors to observe the physical environment of the infrastructure the sensor node 1-9 are installed in. For example, temperature sensor, humidity sensor, altitude sensor, pressure sensor, GPS sensor, water pressure sensor, piezometer, multidepth deflectometers (MDD), etc.

The sensor node 1-9 can be installed to the railway structure depending on the sensor. For example, the strain gauge sensor can be most efficient when installed to the rail. The piezometer can be installed to the sub-ballast. The LVDT sensor can be installed to the sleeper. One sensor node 1-9 can be installed to more than one places.

The sensor node 1-9 can be installed according to a protocol based on routing trees to be able to transmit information to the base station. Once the information has been received, the UMTS technology can be used to send sensor data to a remote server 800. The sensor node 1-9 can comprise an analog-to-digital converter, a micro controller, a transceiver, power and memory. One or more sensor(s) can be embedded in different elements and can be mounted on boards to be attached to the railway infrastructure. The sensor node 1-9 can also comprise materializing strain gauges, displacement transducers, accelerometers, inclinometers, acoustic emission, thermal detectors, among others. The analog signal outputs generated by the sensors can be converted to digital signals that can be processed by digital electronics. The data can then be transmitted to the base station by a microcontroller through a radio transceiver. All devices can be electric or electronic components supported by power supply, which can be provided through batteries or by local energy generation (such as solar panels), the latter mandatory at locations far away from energy supplies.

The sensor data 101 collected from the sensor nodes 1-9 can be transferred to the base station using wireless communication technology such as CAN, FlexRay, Wi-Fi or Bluetooth. For example, the ZigBee network can be advantageous to consumes less power. On the other hand, for transmitting the input 101 data from the base station to the server 800 long-range communication such as GPRS, EDGE, UMTS, LTE or satellite can be used. Due to the short transmission range, communications from sensor nodes may not reach the base station, a problem that can be overcome by adopting relay nodes to pass the data from the sensor nodes 1-9.

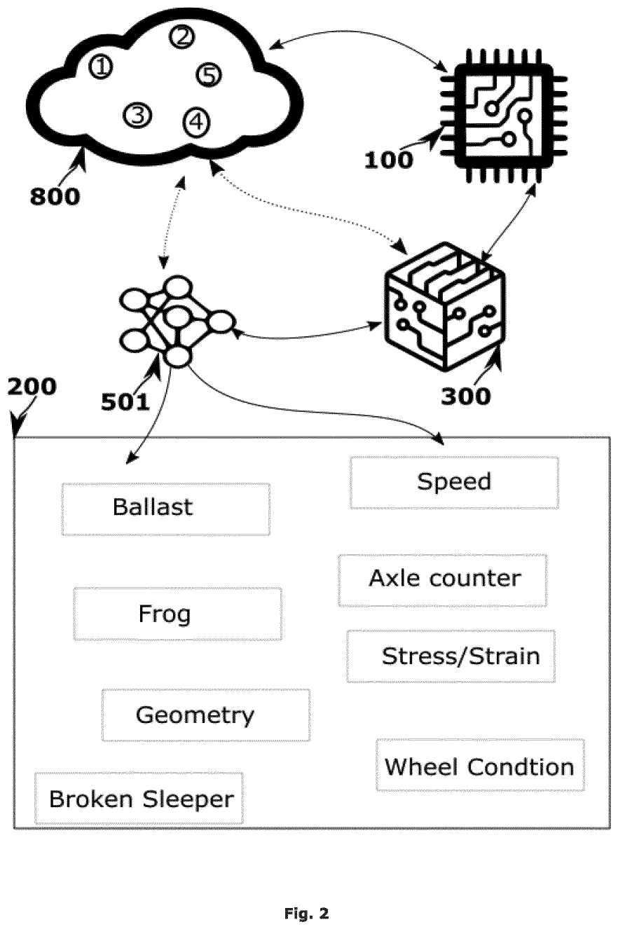

FIG. 2 depicts a system according to an aspect of the present invention. The server 800, The collected sensor data 101 can be transmitted to the server 800 server through long-range communications such as GPRS, EDGE, UMTS, LTE or satellite. The sensor node 1-9 can also communicate directly with the server 800 without requiring the use of the base station as a gateway.

The server 800 may comprise a data transmitting component may be configured to establish a bidirectional communication with the base station. In other words, the server 800 may retrieve sensor data 101 from the base station, and further may provide it to the processing component 100, for example, vibrational data.

In one embodiment, the server 800 may comprise a cloud server, a remote server and/or a collection of different type of servers. Therefore, the server 800 may also be referred to as cloud server 800, remote server 800, or simple as servers 500. In another embodiment, the servers 800 may also converge in a central server.

It will be understood that the server 800 may also be in bidirectional communication with a storage component and an interface component. The storage component may be configured to receive information from the server 800 for storage. In simple words, the storing component 800 may store information provided by the servers 800. The information provided by the server 800 may include, for example, but not limited to, data obtained by sensor nodes 1-9, data processed by the processing component 100 and any additional data generated in the servers 800 or the processing component 800.

It will be understood that the servers 800 may be granted access to the storage component comprising, inter alia, the following dictions about future or otherwise unknown events.

The storage component can comprise comprises a volatile or non-volatile memory, such as a random-access memory (RAM), Dynamic RAM (DRAM), Synchronous Dynamic RAM (SDRAM), static RAM (SRAM), Flash Memory, Magneto-resistive RAM (MRAM), Ferroelectric RAM (F-RAM), or Parameter RAM (P-RAM).

It will also be understood that the term server may also refer to a computer program, and/or a device, and/or a plurality of each or both that may provide functionality for other programs, devices and/or components of the present invention. For instance, a server may provide various functionalities, which may be referred to as services, such as, for example, sharing data or resources among multiple clients, or performing computation and/or storage functions. It will further be understood that a single server may serve multiple clients, and a single client may use multiple servers. Furthermore, a client process may run on the same device or may connect over a network to a server on a different device, such as a remote server or a cloud. The server may have rather primitive functions, such as just transmitting rather short information to another level of infrastructure, or can have a more sophisticated structure, such as a storing, processing and transmitting unit.

The processing component 100 can comprise a CPU (central processing unit), GPU graphical processing unit), DSP (digital signal processor), APU (accelerator processing unit), ASIC (application-specific integrated circuit), ASIP (application-specific instruction-set processor) or FPGA (field programmable gate array) or any combination thereof.

The processing component 100 can further be generating the structured database 103 using the sensor data 101. The structured database 103 may comprise. The processing component 100 can be configured to automatically recognize the sensor associated with the sensor data 101 and can further generate structured database 103 based on the type of the sensor.

The processing component 100 can be configured with machine learning techniques, such as pattern recognition. The processing component can further be configured to generate labeled data using the structured database 103 and/or the sensor data 101.

The processed data, meaning the data transmitting from the processing component 100 which can comprise the structured database and/or the labeled data. The processed data can be then automatically pulled by the model analyzer 300. The model analyzer 300 can comprise generating at least one simulation model 102 based on at least the physical conditions (temperature, waves, speed, etc.).

The model analyzer 300 may comprise of a computer program product which can be configured to be programmed based on at least one of dynamical systems, statistical models, differential equations, game theoretic models, logic. The model analyzer 300 can be equipped with neural networks. The model analyzer 300 can further be configured to automatically learn the at least one of governing equations, assumptions, constraints using an existing knowledgebase. The model analyzer 300 can also learn using the sensor data 101 and/or structured database 103.

The model analyzer 300 can also be configured to generate at least one noise model 104 based on at least one of dynamical systems, statistical models, differential equations, game theoretic models, logic.

The simulation model 102 and/or the noise model 104 generated by the model analyzer 300 can be automatically fed to the weight analyzer 501/500. The weight analyzer 501/500 can comprise a machine learning classifier. The weight analyzer 500/501 may be trained using the simulation model 102 to generate labeled data. The weight analyzer 500/501 can be configured to generate the labeled data by using at least one of k-nearest neighbor, case-based reasoning, artificial neural networks, Naïve Bayes, etc.

The weight analyzer 501/500 can further be configured to predict at least one infrastructural feature (ballast, frog, geometry, speed, etc.) based on the labeled data and can further transmit the results to a user device 200.

The user device 200 can comprise a memory component such as, main memory (e.g. RAM), cache memory (e.g. SRAM) and/or secondary memory (e.g. HDD, SDD). The user device 200 may also comprise at least of an output user interface, such as: screens or monitors configured to display visual data (e.g. displaying graphical user interfaces of the questionnaire to the user), speakers configured to communicate audio data (e.g. playing audio data to the user). The user device 200 can also comprise an input user interface, such as, camera configured to capture visual data (e.g. capturing images and/or videos of the user), microphone configured to capture audio data (e.g. recording audio from the user), and a keyboard configured to allow the insertion of text and/or other keyboard commands (e.g. allowing the user to enter text data and/or another keyboard and mouse, touchscreen, joystick—configured to facilitate the navigation through different graphical user interfaces of the questionnaire.

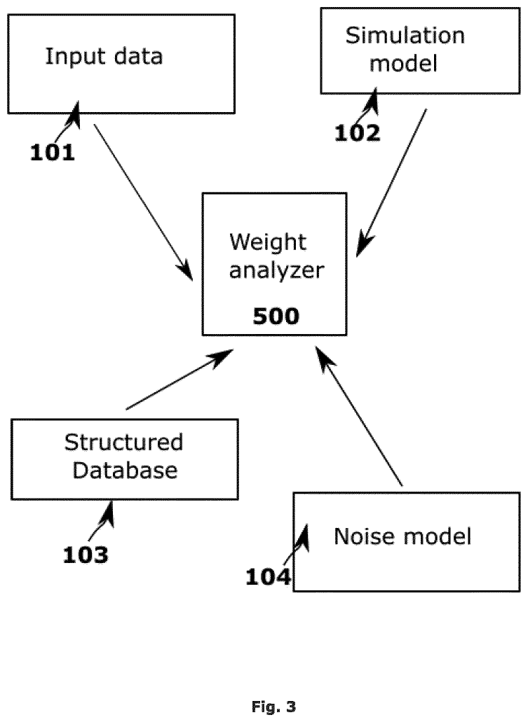

FIG. 3 depicts an embodiment according to the present invention. The figure particularly represents the training phase of the weight analyzer 500. The weight analyzer 500 can comprise ‘self-learning’ of the features. The self-learning of the weight analyzer 500 can be by using the simulation model 102, sensor data 101, structured database 103, noise model 104, etc. The weight analyzer 500 can comprise building at least one machine learning model based on the simulation model 102 and then further associate statistical weights to the at least one feature.

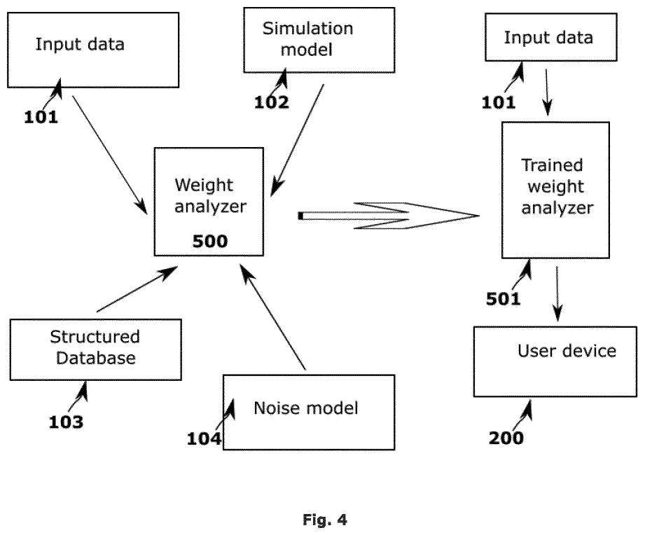

FIG. 4 depicts a deployment phase of the weight analyzer 501, after it is trained. The weight analyzer 501 can be pulling in the sensor data 101 directly from server 800. The weight analyzer 501 may be configured to generate at least one feature prediction and transmit it to the user device 200.

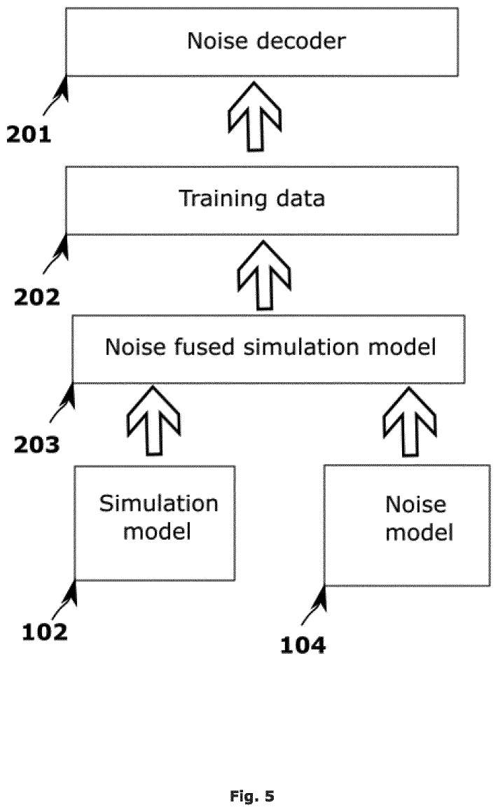

FIG. 5 depicts a method to train the weight analyzer 501/500 using fusion of the noise model 104. The model analyzer 300 can comprise generative machine learning techniques such as an autoencoder to generate at least one noise model 104. The noise model 104 can further be fused with the simulation model 102 to generate the realistic noise fused model 203. The noise fused model 203 can then be used as training data 202 to train the weight analyzer 500/501 to learn to decode the noise 201.

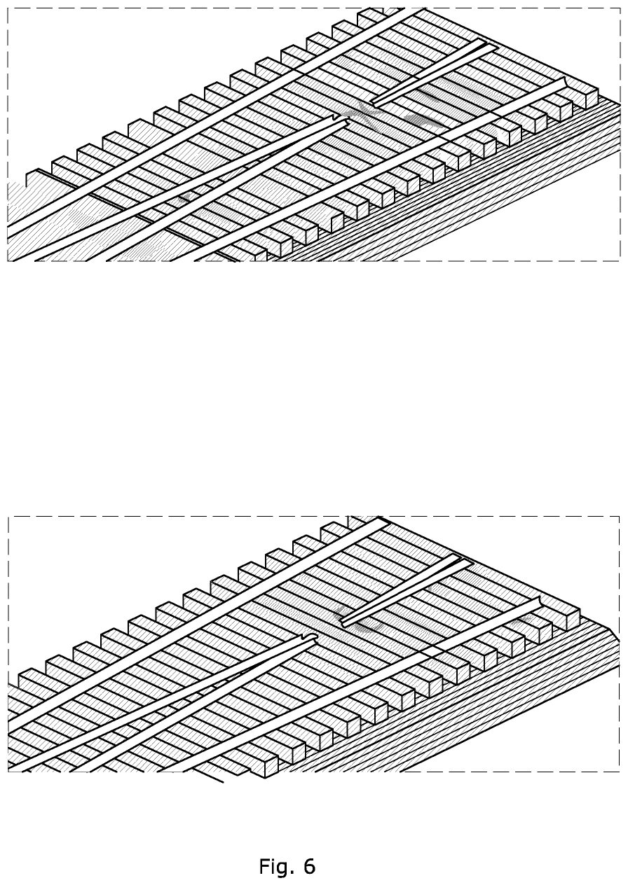

FIG. 6 shows an exemplary representation of load in different aspects of railway infrastructure. Load data may be generated using weight sensor in the railway structure. The weight analyzer 500/501 may be configured to automatically learn at least one feature from the load data. Furthermore, model generator 300 may be configured to automatically generate a degradation model based on the load data. The processing component 100 may further be configured to automatically calculate a load factor, for example between 0.0 and 12.0, based on load data. In some embodiments wherein the load data is directly fed into the model analyzer 300, the model analyzer 300 may be configured to generate the load factor. The load factor may be based on number and/or type and/or speed of trains that passes over the sensor node. The database which may comprise a higher load factor may represent faster degradation. This degradation model can further assist in generating an inspection schedule of the railway infrastructure.

The weight analyzer 500/501 may further be configured to self-learn the at least one feature from the load data, such as quantity of gravel in the railway tracks.

Reference numbers and letters appearing between parentheses in the claims, identifying features described in the embodiments and illustrated in the accompanying drawings, are provided as an aid to the reader as an exemplification of the matter claimed. The inclusion of such reference numbers and letters is not to be interpreted as placing any limitations on the scope of the claims.

The term “at least one of a first option and a second option” is intended to mean the first option or the second option or the first option and the second option.

Whenever a relative term, such as “about”, “substantially” or “approximately” is used in this specification, such a term should also be construed to also include the exact term. That is, e.g., “substantially straight” should be construed to also include “(exactly) straight”.

Whenever steps were recited in the above or also in the appended claims, it should be noted that the order in which the steps are recited in this text may be accidental. That is, unless otherwise specified or unless clear to the skilled person, the order in which steps are recited may be accidental. That is, when the present document states, e.g., that a method comprises steps (A) and (B), this does not necessarily mean that step (A) precedes step (B), but it is also possible that step (A) is performed (at least partly) simultaneously with step (B) or that step (B) precedes step (A). Furthermore, when a step (X) is said to precede another step (Z), this does not imply that there is no step between steps (X) and (Z). That is, step (X) preceding step (Z) encompasses the situation that step (X) is performed directly before step (Z), but also the situation that (X) is performed before one or more steps (Y1), . . . , followed by step (Z). Corresponding considerations apply when terms like “after” or “before” are used.

1. A system, comprising:
a. at least one processing component;
b. at least one storage component;
c. a plurality of sensor nodes;
wherein, the processing component is configured to receive sensor data from the at least one sensor node,
d. at least one model analyzer, configured to generate at least one simulation model; and
e. a weight analyzer, configured to automatically associate a statistical weight to at least one infrastructural feature.

2. The system according to claim 1 wherein the weight analyzer is configured with machine learning techniques, such as deep learning techniques, further configured to self-leam at least one infrastructural feature.

3. The system according to claim 1 wherein the sensor node comprises a pressure sensor and/or accelerometer and/or inclinometer and/or thermal sensor and/or acoustic sensor and/or strain gauge sensor and/or water pressure sensor and/or linear variable displacement sensor and/or visual sensor and/or load sensors and/or any combination thereof.

4. The system according to claim 1 wherein the model analyzer is further configured to automatically generate the at least one infrastructural feature using the simulation model.

5. The system according to claim 1 wherein the processing component is configured to generate a database using the sensor data.

6. The system according to claim 1 wherein the processing component is further configured to automatically classify at least a portion of the database, using the machine learning techniques, such as pattern recognition.

7. The system according to claim 1 wherein the processing component is further configured to store the database and/or classified database in the storage component.

8. The system according to claim 1 wherein the model analyzer is configured to generate the simulation model based on finite element method and/or multi-body simulation method and/or finite difference method and/or lumped parameter method and/or any combination thereof.

9. The system according to claim 1 wherein the system further comprises a noise decoder, the noise decoder comprises machine learning techniques, and is configured to automatically determine a noise pattern in the database.

10. The system according to claim 1 wherein the model analyzer is configured to generate at least one noise model, based on the database, and further configured to fuse the noise model to the simulation model.

11. The system according to claim 1 wherein the model analyzer is further configured to generate at least a portion of the simulation model based on a user input.

12. A method, comprising the steps of:
a. obtaining sensor data from at least one or a plurality of sensor node(s);
b. generating simulation model(s);
c. automatically fusing at least portion of the sensor data with the simulation model; and
d. automatically predicting at least one infrastructural feature, preferably associated with the sensor node.

13. The method according to claim 12 wherein the method comprises the step of carrying out the method on the system according to claim 1.

14. A device comprising:
a. a device processing component, configured for an interactive model analysis;
b. an interface, configured to pull user input; and
c. a memory component, configured to store the user input.

15. A computer program product comprising instructions, when the program is executed by any of the system claims causes the system to perform the method steps according to any of the method claims.
